(19) United States
(12) Patent Application Publication
(10) Pub. No.: US 2025/0018684 A1
(43) Pub. Date: Jan. 16, 2025

(54) COVER MEMBER, DOUBLE-SIDED ADHESIVE SHEET, SEAL MEMBER, AND SHEET FOR SUPPLYING MEMBER

(71) Applicant: NITTO DENKO CORPORATION, Osaka (JP)

(72) Inventors: Kyoko ISHII, Osaka (JP); Yosuke SUGAYA, Osaka (JP); Takeo INOUE, Osaka (JP); Tomohiro KONTANI, Osaka (JP); Shimpei YAKUWA, Osaka (JP); Shunji IMAMURA, Osaka (JP)

(73) Assignee: NITTO DENKO CORPORATION, Osaka (JP)

(21) Appl. No.: 18/687,541

(22) PCT Filed: Aug. 31, 2022
(86) PCT No.: PCT/JP2022/032885

§ 371 Date: Feb. 28, 2024

(30) Foreign Application Priority Data
Aug. 31, 2021 (JP) 2021-141965

(51) Int. Cl. B32B 17/10; B32B 3/26; B32B 5/02; B32B 5/16; B32B 5/18; B32B 17/06; B32B 27/06; B32B 27/08; B32B 27/12; B32B 27/14; B32B 27/28; B32B 27/32; H01L 23/10

(52) U.S. Cl. CPC B32B 17/10; B32B 3/263; B32B 5/028; B32B 5/16; B32B 5/18; B32B 17/066; B32B 17/067; B32B 17/068; B32B 27/065; B32B 27/08; B32B 27/12; B32B 27/14; B32B 27/28; B32B 27/322; H01L 23/10; B32B 2255/10; B32B 2255/26; B32B 2262/0284; B32B 2264/0257; B32B 2264/1021; B32B 2264/12; B32B 2266/0207; B32B 2266/0242; B32B 2307/306; B32B 2307/412; B32B 2307/546; B32B 2307/7242; B32B 2307/737; B32B 2307/7375; B32B 2307/7376; B32B 2405/00; B32B 2581/00

(57) ABSTRACT

A cover member suitable for suppressing damage to a semiconductor device package includes: a cover sheet having a shape configured to cover an object in a state of being placed on a placement face; and an adhesive layer joined to the cover sheet and configured to fix the cover member to the placement face. The adhesive layer includes a double-sided adhesive sheet. The double-sided adhesive sheet has a structure in which a first adhesive agent layer, a substrate, and a second adhesive agent layer are laminated in this order. The substrate has a porous structure. The substrate has a porosity of 30% or more. When the porosity of the substrate is 30% or more and 50% or less, the substrate has an average pore diameter of 10 μm or more, and when the porosity of the substrate is more than 50%, the average pore diameter is 0.05 μm or more.

### TECHNICAL FIELD

The present invention relates to a cover member and a double-sided adhesive sheet that can be included in the cover member. The present invention also relates to a seal member that can be manufactured using the double-sided adhesive sheet and a member supplying sheet including the cover member or the seal member.

### BACKGROUND ART

Cover members configured to be placed on a placement face so as to cover an object are known. One example of cover members is a member used for semiconductor device packages. Patent Literature 1 discloses a member configured to be placed on a semiconductor substrate as a placement face so as to cover a functional element on the semiconductor substrate, and a semiconductor device package including the member.

The member of Patent Literature 1 includes a cap substrate placed at a predetermined interval from one face of the semiconductor substrate so as to face the one face, and a sealing member placed around the functional element and joining the semiconductor substrate and the cap substrate together.

### CITATION LIST

### Patent Literature

Patent Literature 1: JP 2009-43893 A

### SUMMARY OF INVENTION

### Technical Problem

The sealing member of Patent Literature 1 includes a moisture-permeable resin layer for the purpose of preventing condensation in the semiconductor device package. However, studies by the present inventors have revealed that when the moisture-permeable resin layer is merely included, damage to the package may occur when the pressure (internal pressure) inside the package increases significantly due to a high-temperature treatment such as reflow soldering, for example. According to the studies, it is inferred that the fact that the moisture-permeable resin layer is generally a layer that allows water vapor to permeate using physical diffusion is the reason why it is difficult to cope with the above increase in internal pressure.

The present invention aims to provide a cover member suitable for suppressing damage to a semiconductor device package due to an increase in internal pressure.

### Solution to Problem

The present invention provides a cover member configured to be placed on a placement face so as to cover an object, the cover member including:
a cover sheet having a shape configured to cover the object in a state of being placed on the placement face; and
an adhesive layer joined to the cover sheet and configured to fix the cover member to the placement face, wherein
the adhesive layer includes a double-sided adhesive sheet,
the double-sided adhesive sheet has a structure in which a first adhesive agent layer, a substrate, and a second adhesive agent layer are laminated in this order,
the substrate has a porous structure,
the substrate has a porosity of 30% or more,
when the porosity of the substrate is 30% or more and 50% or less, the substrate has an average pore diameter of 10 μm or more, and
when the porosity of the substrate is more than 50%, the average pore diameter is 0.05 μm or more.

In another aspect, the present invention provides a member supplying sheet including:
a substrate sheet; and
at least one cover member placed on the substrate sheet, wherein
the cover member is the cover member of the present invention.

In another aspect, the present invention provides a double-sided adhesive sheet having a structure in which a first adhesive agent layer, a substrate, and a second adhesive agent layer are laminated in this order, wherein
the substrate has a porous structure,
the substrate has a porosity of 30% or more,
when the porosity of the substrate is 30% or more and 50% or less, the substrate has an average pore diameter of 10 μm or more, and
when the porosity of the substrate is more than 50%, the average pore diameter is 0.05 μm or more.

With the double-sided adhesive sheet of the present invention, for example, it is possible to obtain a seal member suitable for ensuring air permeability while preventing passage of foreign matter. In this aspect different from the above, the present invention provides a seal member configured to be placed between a first component and a second component when the first component and the second component are joined, and prevent passage of foreign matter between an inner space surrounded by the first component and the second component joined together and an outside, wherein
the seal member has an air flow path between the inner space and the outside,
the seal member comprises the double-sided adhesive sheet of the present invention, and
the substrate of the double-sided adhesive sheet is included in the air flow path.

In another aspect, the present invention provides a member supplying sheet including:
a substrate sheet; and
at least one seal member placed on the substrate sheet, wherein
the seal member is the seal member of the present invention.

### Advantageous Effects of Invention

The cover member of the present invention is suitable for suppressing damage to a semiconductor device package due to an increase in internal pressure.

### BRIEF DESCRIPTION OF THE DRAWINGS

FIG. 1A is a cross-sectional view schematically showing an example of a cover member of the present invention.

FIG. 1B is a plan view of the cover member of FIG. 1A viewed from an adhesive layer 13 side.

FIG. 2 is a cross-sectional view schematically showing an example of a double-sided adhesive sheet that can be used for the cover member of the present invention.

FIG. 3 is a schematic diagram for describing a method for evaluating a side air permeation amount of a substrate that can be included in the double-sided adhesive sheet that can be used for the cover member of the present invention.

FIG. 4 is a schematic diagram for describing a method for evaluating a membrane thickness ratio of the substrate that can be included in the double-sided adhesive sheet that can be used for the cover member of the present invention.

FIG. 5 is a schematic diagram for describing a method for evaluating a side water entry pressure of the substrate that can be included in the double-sided adhesive sheet that can be used for the cover member of the present invention.

FIG. 6 is a cross-sectional view schematically showing an example of another cover member of the present invention.

FIG. 7 is a cross-sectional view schematically showing an example of a semiconductor device package that can be manufactured using the cover member of the present invention.

FIG. 8 is a perspective view schematically showing an example of a seal member of the present invention.

FIG. 9A is an exploded perspective view schematically showing an example of the usage of the seal member of the present invention.

FIG. 9B is a cross-sectional view schematically showing an example of the usage of the seal member of the present invention.

FIG. 10 is a plan view schematically showing an example of a member supplying sheet of the present invention.

### DESCRIPTION OF EMBODIMENTS

A cover member according to a first aspect of the present invention is a cover member configured to be placed on a placement face so as to cover an object, the cover member including:
a cover sheet having a shape configured to cover the object in a state of being placed on the placement face; and
an adhesive layer joined to the cover sheet and configured to fix the cover member to the placement face, wherein
the adhesive layer includes a double-sided adhesive sheet,
the double-sided adhesive sheet has a structure in which a first adhesive agent layer, a substrate, and a second adhesive agent layer are laminated in this order,
the substrate has a porous structure,
the substrate has a porosity of 30% or more,
when the porosity of the substrate is 30% or more and 50% or less, the substrate has an average pore diameter of 10 μm or more, and
when the porosity of the substrate is more than 50%, the average pore diameter is 0.05 μm or more.

In a second aspect of the present invention, for example, in the cover member according to the first aspect, the substrate contains a heat-resistant material.

In a third aspect of the present invention, for example, in the cover member according to the second aspect, the heat-resistant material is at least one selected from a fluorine resin and a silicon compound.

In a fourth aspect of the present invention, for example, in the cover member according to any one of the first to third aspects, the substrate is a stretched porous resin sheet or a porous particle aggregated sheet.

In a fifth aspect of the present invention, for example, in the cover member according to any one of the first to fourth aspects, the substrate has a deformation ratio of 60% or less in a thickness direction thereof when the substrate is compressed in the thickness direction at a pressure of 30 MPa.

In a sixth aspect of the present invention, for example, in the cover member according to any one of the first to fifth aspects, the substrate has a deformation ratio of 20% or less in a thickness direction thereof when the substrate is compressed in the thickness direction at a pressure of 0.5 MPa.

In a seventh aspect of the present invention, for example, in the cover member according to any one of the first to sixth aspects, the substrate has a side air permeation amount of 0.005 mL/min/kPa or more.

In an eighth aspect of the present invention, for example, in the cover member according to any one of the first to seventh aspects, at least one selected from the first adhesive agent layer and the second adhesive agent layer is a pressure-sensitive adhesive agent layer.

In a ninth aspect of the present invention, for example, in the cover member according to any one of the first to eighth aspects, at least one selected from the first adhesive agent layer and the second adhesive agent layer is an acrylic adhesive agent layer or a silicone adhesive agent layer.

In a tenth aspect of the present invention, for example, in the cover member according to any one of the first to ninth aspects, the adhesive layer has re-peelability from the placement face.

In an eleventh aspect of the present invention, for example, in the cover member according to the tenth aspect, the adhesive layer has an adhesive strength of 0.05 N/20 mm or more and less than 5.0 N/20 mm to the placement face.

In a twelfth aspect of the present invention, for example, in the cover member according to the tenth or eleventh aspect, the adhesive layer includes the double-sided adhesive sheet and a re-peelable adhesive agent layer, and the cover member is placed on the placement face via the re-peelable adhesive agent layer.

In a thirteenth aspect of the present invention, for example, in the cover member according to any one of the first to twelfth aspects, the adhesive layer has a shape corresponding to a peripheral portion of the cover sheet when viewed in a direction perpendicular to a principal surface of the cover sheet, and is joined to the peripheral portion.

In a fourteenth aspect of the present invention, for example, in the cover member according to any one of the first to thirteenth aspects, the cover sheet has no air permeability in a thickness direction thereof.

In a fifteenth aspect of the present invention, for example, in the cover member according to any one of the first to fourteenth aspects, the cover sheet is an optically transparent sheet.

In a sixteenth aspect of the present invention, for example, in the cover member according to any one of the first to fifteenth aspects, the cover sheet contains at least one selected from a heat-resistant resin and glass.

In a seventeenth aspect of the present invention, for example, in the cover member according to the sixteenth aspect, the heat-resistant resin is polyimide.

In an eighteenth aspect of the present invention, for example, in the cover member according to any one of the first to seventeenth aspects, the cover sheet includes an optical lens.

In a nineteenth aspect of the present invention, for example, in the cover member according to any one of the first to eighteenth aspects, the cover sheet has an area of 3500 mm² or less.

In a twentieth aspect of the present invention, for example, in the cover member according to any one of the first to nineteenth aspects, the cover member is placed so as to cover a semiconductor device with a face of a substrate on which the semiconductor device is mounted being the placement face, and the cover member is used for forming a semiconductor device package in which the semiconductor device is housed in an inner space of the semiconductor device package by placing the cover member on the placement face.

A member supplying sheet according to a twenty-first aspect of the present invention includes:
a substrate sheet; and
at least one cover member placed on the substrate sheet, wherein
the cover member is the cover member according to any one of the first to twentieth aspects.

A double-sided adhesive sheet according to a twenty-second aspect of the present invention has a structure in which a first adhesive agent layer, a substrate, and a second adhesive agent layer are laminated in this order, wherein
the substrate has a porous structure,
the substrate has a porosity of 30% or more,
when the porosity of the substrate is 30% or more and 50% or less, the substrate has an average pore diameter of 10 μm or more, and
when the porosity of the substrate is more than 50%, the average pore diameter is 0.05 μm or more.

A seal member according to a twenty-third aspect of the present invention is a seal member configured to be placed between a first component and a second component when the first component and the second component are joined, and prevent passage of foreign matter between an inner space surrounded by the first component and the second component joined together and an outside, wherein
the seal member has an air flow path between the inner space and the outside,
the seal member includes the double-sided adhesive sheet according to the twenty-second aspect, and
the substrate of the double-sided adhesive sheet is included in the air flow path.

In a twenty-fourth aspect of the present invention, for example, the seal member according to the twenty-third aspect has a ring shape or a frame shape.

In a twenty-fifth aspect of the present invention, for example, in the seal member according to the twenty-fourth aspect, a region surrounded by the seal member has an area of 50 cm² or more.

In a twenty-sixth aspect of the present invention, for example, the seal member according to any one of the twenty-third to twenty-fifth aspects has a width of 5 mm or less.

A member supplying sheet according to a twenty-seventh aspect of the present invention includes:
a substrate sheet; and
at least one seal member placed on the substrate sheet, wherein
the seal member is the seal member according to any one of the twenty-third to twenty-sixth aspects.

Hereinafter, embodiments will be described with reference to the drawings. The present invention is not limited to the embodiments described below.

### [Cover Member]

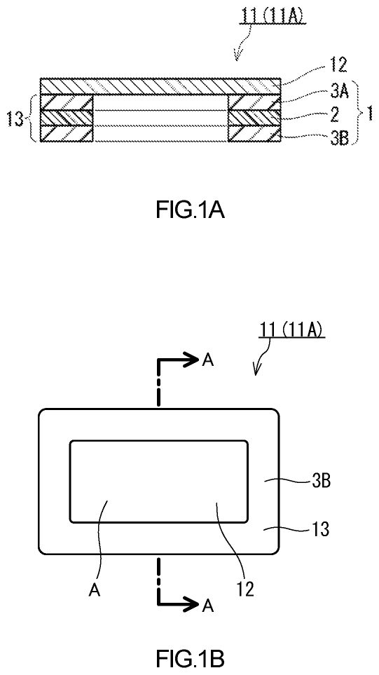

FIGS. 1A and 1B show an example of a cover member of the present embodiment. FIG. 1B is a plan view of a cover member 11 (11A) of FIG. 1A viewed from a second adhesive agent layer 3B (side of placement on a placement face). FIG. 1A shows a cross-section A-A of FIG. 1B. The cover member 11 is a member configured to be placed on a placement face so as to cover an object (object to be covered), and can be used for covering the object. The placement face may be a face of the object, or a face of a member other than the object (for example, a substrate on which the object is placed). The cover member 11 includes a cover sheet 12 and an adhesive layer 13. The cover sheet 12 has a shape configured to cover the object in a state where the cover member 11 is placed on the placement face. The adhesive layer 13 is joined to the cover sheet 12 and fixes the cover member 11 to the placement face. In other words, the cover member 11 is fixed to the placement face via the adhesive layer 13. The adhesive layer 13 includes a double-sided adhesive sheet 1. The adhesive layer 13 of FIG. 1A and FIG. 1B is composed of the double-sided adhesive sheet 1.

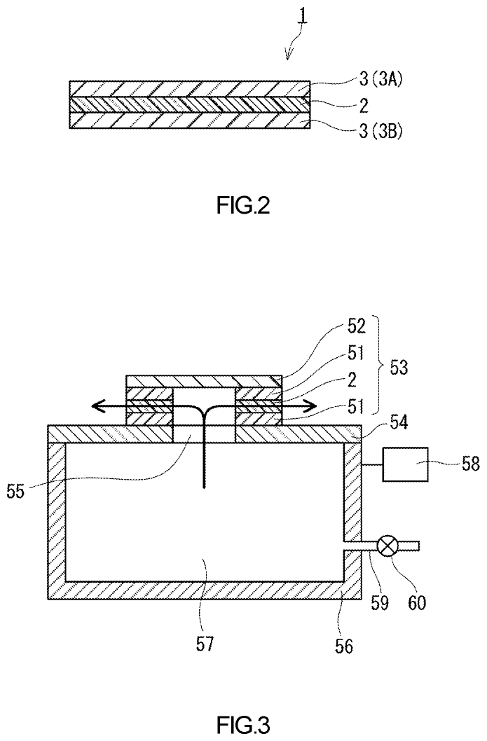

FIG. 2 shows an example of the double-sided adhesive sheet 1. The double-sided adhesive sheet 1 of FIG. 2 includes a first adhesive agent layer 3 (3A), a substrate 2, and a second adhesive agent layer 3 (3B). The double-sided adhesive sheet 1 has a structure in which the first adhesive agent layer 3A, the substrate 2, and the second adhesive agent layer 3B are laminated in this order. The substrate 2 has a porous structure. The porosity of the substrate 2 is 30% or more. (1) When the porosity of the substrate 2 is 30% or more and 50% or less, the average pore diameter of the substrate 2 is 10 μm or more, and (2) when the porosity of the substrate 2 is more than 50%, the average pore diameter of the substrate 2 is 0.05 μm or more. The substrate 2 satisfying the above relationships with respect to the porosity and the average pore diameter, and the double-sided adhesive sheet 1 including the substrate 2 can contribute to suppressing damage to a semiconductor device package due to an increase in internal pressure.

The upper limit of the porosity of the substrate 2 is, for example, 95% or less, and may be 93% or less, 90% or less, 87% or less, or even 85% or less. The lower limit of the porosity of the substrate 2 may be 32% or more, 35% or more, 40% or more, 45% or more, or even 50% or more. However, the porosity of the substrate 2 may be in different ranges depending on the material of the substrate 2.

The porosity of the substrate 2 can be evaluated as follows. The substrate 2 to be evaluated is cut into a certain size (for example, a circular shape having a diameter of 47 mm), and the volume and the weight thereof are obtained. The obtained volume and weight are substituted into the following formula (1) to calculate the porosity of the substrate 2. In the formula (1), V denotes the volume (cm³), W denotes the weight (g), and D denotes the true density (g/cm³) of the material forming the substrate 2. The porosity of the substrate 2 in the state of the double-sided adhesive sheet 1 can be calculated, for example, by determining the volume V and the weight W of the substrate 2 from which the adhesive agent layer 3 is removed by dissolution or peeling, and substituting the volume V and the weight W into the formula (1).

Porosity (%)=100×[V−(W/D)]/V (1)

The upper limit of the average pore diameter (hereinafter referred to as average pore diameter LA) of the substrate 2 is, in the case of (1) above, for example, 100 μm or less, and may be 90 μm or less, 85 μm or less, 80 μm or less, 75 μm or less, 70 μm or less, 65 μm or less, 55 μm or less, 50 μm or less, 45 μm or less, 40 μm or less, 35 μm or less, or even 30 μm or less. The lower limit of the average pore diameter LA of the substrate 2 in the case of (1) above may be 11 μm or more, 12 μm or more, 13 μm or more, 14 μm or more, 15 μm or more, 20 μm or more, 25 μm or more, or even 30 μm or more. The upper limit of the average pore diameter LA of the substrate 2 in the case of (2) above is, for example, 30 μm or less, and may be 25 μm or less, 15 μm or less, 10 μm or less, 8 μm or less, 7 μm or less, 5 μm or less, 4 μm or less, or even 3 μm or less. The lower limit of the average pore diameter LA of the substrate 2 in the case of (2) above may be 0.1 μm or more, 0.2 μm or more, 0.5 μm or more, 0.7 μm or more, or even 1 μm 5 or more. However, the average pore diameter LA of the substrate 2 may be in different ranges depending on the material of the substrate 2.

The average pore diameter LA of the substrate 2 can be evaluated, for example, as follows. An enlarged image is obtained by a magnification observation method with a scanning electron microscope (SEM) or the like on a cross-section, in the thickness direction, cut out with a microtome, a feather blade, or the like from the substrate 2 to be evaluated in a state where the substrate 2 is frozen with liquid nitrogen. The freezing with liquid nitrogen is intended to suppress pore deformation during cutting-out. The magnification observation can be performed at room temperature (25° C.±5° C.). The magnification of the enlarged image is preferably 300 to 5000 times. The area of the range where the enlarged image is obtained is preferably 20 to 4000 μm². The cross-section of the substrate 2 in the state of the double-sided adhesive sheet 1 can be obtained by cutting the double-sided adhesive sheet 1 in a frozen state. However, it is preferable to cut out the cross-section while avoiding the end portions of the double-sided adhesive sheet 1 (which may be deformed depending on the environment of distribution and storage), and the cross-section may be cut out near the center of the double-sided adhesive sheet 1 viewed in a direction perpendicular to a principal surface of the sheet 1 (near the center in the width direction of the double-sided adhesive sheet 1 when the double-sided adhesive sheet 1 is in the form of a strip). The number of cross-sections to be observed is one or more, and when two or more cross sections are observed, it is preferable to change the location for each cross-section. There may be overlap in the cross-sections to be observed. The cross-section to be observed for the double-sided adhesive sheet 1 in the form of a strip may be a cross-section viewed from a side surface in the width direction. The cross-section to be observed for the double-sided adhesive sheet 1 included in a cover member or a sheet member may be a cross-section perpendicular to a direction in which an air flow path in these members extends. When the double-sided adhesive sheet 1 (for example, the substrate 2 thereof) has a MD (Machine Direction) and TD (Transverse Direction), a cross section extending in the MD or TD may be observed. Next, image analysis is performed on the enlarged image of the cross-section to binarize the image into pores and the other portions. Image analysis software such as Image J can be used for the image analysis. Based on the binarized image, a total pore area S (μm²) and the number of pores N are calculated, and the average pore diameter LA of the cross-section is calculated using the following formula (2). When two or more cross-sections are observed, the average value of the calculated average pore diameters LA of the respective cross-sections can be determined as the average pore diameter LA of the substrate 2.

Average pore diameter LA (μm)=(S/(N×π))^{1/2}×2 (2)

Examples of the material contained in the substrate 2 include a metal, a metal compound, a resin, and a composite material thereof.

Examples of the resin that can be contained in the substrate 2 include polyolefins such as polyethylene and polypropylene, polyesters such as polyethylene terephthalate (PET), silicone resins, polycarbonates, polyimides, polyamide-imides, polyphenylene sulfide, polyetheretherketone (PEEK), and fluorine resins. Examples of the fluorine resins include PTFE, tetrafluoroethylene-perfluoroalkyl vinyl ether copolymer (PFA), tetrafluoroethylene-hexafluoropropylene copolymer (FEP), and tetrafluoroethylene-ethylene copolymer (ETFE). However, the resin is not limited to the above examples.

Examples of the metal that can be contained in the substrate 2 include stainless steel and aluminum. Examples of the metal compound that can be contained in the substrate 2 include a metal oxide, a metal nitride, and a metal oxynitride. The metal includes silicon. The metal compound may be a silicon compound such as silica.

The substrate 2 may contain a heat-resistant material. The substrate 2 containing a heat-resistant material is suitable for use in a cover member that is subjected to a high-temperature treatment such as reflow soldering, for example. Examples of the heat-resistant material include a metal, a metal compound, and a heat-resistant resin. The heat-resistant resin typically has a melting point of 150° C. or higher. The heat-resistant resin may have a melting point of 160° C. or higher, 200° C. or higher, 250° C. or higher, 260° C. or higher, or even 300° C. or higher. Examples of the heat-resistant resin include a silicone resin, a polyimide, a polyamide-imide, polyphenylene sulfide, PEEK, and a fluorine resin. The fluorine resin may be PTFE. PTFE is excellent particularly in heat resistance. An example of the metal compound that is a heat-resistant material is a silicon compound. The heat-resistant material may be at least one selected from a fluorine resin and a silicon compound.

The substrate 2 may be a stretched porous resin sheet or a porous particle aggregated sheet. However, the structure of the substrate 2 is not limited to the above examples as long as the substrate 2 has a porous structure and the porosity and the average pore diameter LA of the substrate 2 satisfy the above relationships. The substrate 2 may be a foam, a mesh, or the like.

The stretched porous resin sheet (hereinafter referred to as stretched porous sheet) may be a stretched porous fluorine resin sheet, or a stretched porous PTFE sheet. The stretched porous PTFE sheet is usually formed by stretching a paste extrusion or cast membrane containing PTFE particles. The stretched porous PTFE sheet is usually formed of fine PTFE fibrils and can have a node in which PTFE is more highly aggregated than in the fibrils. However, the stretched porous sheet is not limited to the above examples.

Examples of the particles contained in the porous particle aggregated sheet (hereinafter referred to as porous aggregated sheet) include resin particles, metal particles, and metal compound particles. Examples of the resin, the metal, and the metal compound, including a heat-resistant material, are as described above. Examples of the porous aggregated sheet include a sintered sheet of ultrahigh-molecular-weight polyethylene particles, an aggregated sheet of silica particles (such as fumed silica sheet), and a sintered sheet of fluorine resin particles. The porous aggregated sheet may be a sintered sheet of fluorine resin particles. However, the porous aggregated sheet is not limited to the above examples.

The substrate 2 typically has permeable communication holes in the in-plane direction thereof. The stretched porous resin sheet and the porous particle aggregated sheet usually have communication holes. The substrate 2 may or may not have independent holes.

When the substrate 2 is a stretched porous sheet, the lower limit of the porosity may be 50% or more, 55% or more, 60% or more, 65% or more, or even 70% or more. The upper limit of the porosity may be 93% or less, 90% or less, 87% or less, or even 85% or less.

When the substrate 2 is a stretched porous sheet, the lower limit of the average pore diameter LA may be 0.07 μm or more, 0.1 μm or more, 0.3 μm or more, 0.5 μm or more, 0.7 μm or more, 0.8 μm or more, 0.9 μm or more, or even 1.0 μm or more. The upper limit of the average pore diameter LA may be 5.0 μm or less, 4.0 μm or less, 3.0 μm or less, 2.5 μm or less, 2.0 μm or less, or even 1.5 μm or less.

When the substrate 2 is a porous aggregated sheet, the lower limit of the porosity may be 30% or more, 32% or more, 35% or more, 40% or more, 45% or more, 50% or more, 55% or more, or even 60% or more. The upper limit of the porosity may be 90% or less, 85% or less, or even 82% or less.

When the substrate 2 is a porous aggregated sheet, the lower limit of the average pore diameter LA may be 0.05 μm or more, 0.07 μm or more, or even 0.08 μm or more. The upper limit of the average pore diameter LA may be 1.0 μm or less, 0.5 μm or less, 0.4 μm or less, 0.3 μm or less, or even 0.2 μm or less.

When the substrate 2 is a porous aggregated sheet, the lower limit of the average pore diameter LA may be 10 μm or more, 20 μm or more, 25 μm or more, or even 30 μm or more. The upper limit of the average pore diameter LA may be 100 μm or less, 90 μm or less, 85 μm or less, 80 μm or less, 75 μm or less, or even 70 μm or less.

The thickness of the substrate 2 is, for example, 10 to 1000 μm, and may be 15 to 700 μm, 20 to 500 μm, 25 to 400 μm, 30 to 300 μm, or even 35 to 200 μm.

The substrate 2 may have a side air permeation amount of, for example, 0.005 5 mL/min/kPa or more. The lower limit of the side air permeation amount may be 0.01 mL/min/kPa or more, 0.03 mL/min/kPa or more, 0.05 mL/min/kPa or more, 0.08 mL/min/kPa or more, 0.1 mL/min/kPa or more, 0.2 mL/min/kPa or more, 0.3 mL/min/kPa or more, 0.5 mL/min/kPa or more, or even 1 mL/min/kPa or more. The upper limit of the side air permeation amount is, for example, 10 mL/min/kPa or less, and may be 8 mL/min/kPa or less, 5 mL/min/kPa or less, 4 mL/min/kPa or less, 3 mL/min/kPa or less, 2 mL/min/kPa or less, 1.5 mL/min/kPa or less, 1 mL/min/kPa or less, 0.8 mL/min/kPa or less, 0.6 mL/min/kPa or less, 0.5 mL/min/kPa or less, or even 0.4 mL/min/kPa or less. The substrate 2 having a side air permeation amount in the above range can contribute to suppressing damage to a semiconductor device package due to an increase in internal pressure.

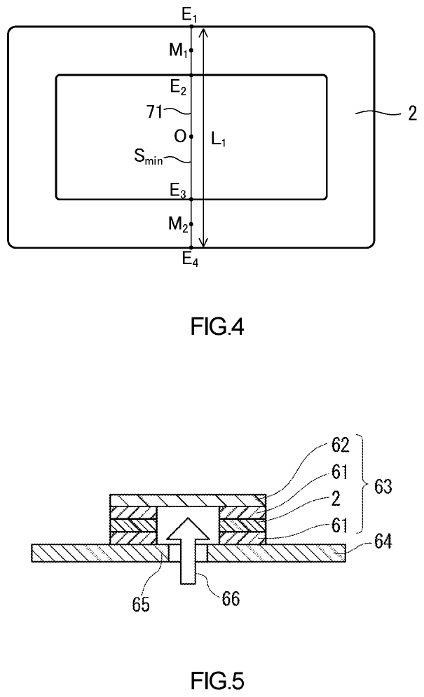

The method for evaluating the side air permeation amount of the substrate 2 will be described with reference to FIG. 3. A double-sided adhesive tape 51 having the same shape as the substrate 2 to be evaluated is attached to one face of the substrate 2. Next, the substrate 2 to which the double-sided adhesive tape 51 is attached is cut out into a frame shape having an outer shape of a 4.4 mm square and an inner shape of a 1.9 mm square (both the outer shape and the inner shape are squares). The cutting-out is performed at room temperature with a punching blade. Although the pores of the substrate 2 may be deformed during punching, since punching is generally performed when forming an adhesive layer of a cover member from the double-sided adhesive sheet 1, the side air permeation amount is a value obtained by taking into consideration the deformation of the pores due to punching. Next, a double-sided adhesive tape 51 having the same shape as the substrate 2 is further attached to the exposed surface of the substrate 2 in the cut-out laminate of the substrate 2 and the double-sided adhesive tape 51. The double-sided adhesive tape 51 is attached to each face of the substrate 2 such that the outer peripheries of the substrate 2 and the double-sided adhesive tape 51 are aligned with each other. As each double-sided adhesive tape 51, a tape that itself has no air permeability in the lateral direction thereof and has sufficient adhesiveness to prevent the tape from peeling off when the side air permeation amount is evaluated can be selected. The double-sided adhesive tape 51 may be a tape unprovided with a substrate. Next, a PET sheet 52 having an outer shape of a 5.4 mm square is attached to the exposed surface of one double-sided adhesive tape 51 to obtain a test piece 53. The PET sheet 52 is attached so as to completely cover the one double-sided adhesive tape 51. As the PET sheet 52, a sheet that has no air permeability in the thickness direction and the lateral direction thereof and does not deform significantly when the side air permeation amount is evaluated can be selected.

Next, the test piece 53 is fixed to a lid portion 54 of an evaluation jig via the other double-sided adhesive tape 51. The lid portion 54 is provided with an opening 55 having an area sufficient to evaluate the side air permeation amount (for example, having a circular cross-sectional shape with a diameter of 1 mm). The test piece 53 is fixed to the lid portion 54 such that air can flow between the inner space of the substrate 2 and the double-sided adhesive tape 51, which have a ring shape, and the opening 55. Depending on the shape of a cross-section of the opening 55, the test piece 53 may be fixed such that the inner circumferential surface of the substrate 2 and the double-sided adhesive tape 51 and the wall surface of the opening 55 coincide with each other when viewed in a direction perpendicular to a surface of the lid portion 54 to which the test piece 53 is fixed. The evaluation jig includes the lid portion 54 and a body portion 56. A space 57 having a certain volume V₁ (mL) is formed inside the evaluation jig in a state where the lid portion 54 is mounted on the body portion 56. V₁ is, for example, 50 to 100 mL and may be 70 mL. In one example of the evaluation jig, the lid portion 54 and the body portion 56 are formed from a metal such as stainless steel. A pressure gauge 58 is connected to the body portion 56, and a pressure P of the space 57 can be measured continuously over time. Also, a pipe 59 is connected to the body portion 56, and air can be supplied to the space 57 via a valve 60.

In a state where the lid portion 54 to which the test piece 53 is fixed is mounted on the body portion 56 (the lid portion 54 is mounted such that the test piece 53 is located on the outer side of the evaluation jig with respect to the lid portion 54), air is supplied to the space 57 to make the pressure P of the space 57 reach 20 kPa (relative pressure). When the pressure P reaches 20 kPa, the valve 60 is closed, and the change in the pressure P is measured over time. The measurement is performed at room temperature. The side air permeation amount of the substrate is calculated using the following formula (3) where the time when the valve 60 is closed is denoted by T₁ (minutes), and the time when the pressure P decreases by 1 kPa from the pressure P=20 kPa to reach 19 kPa is denoted by T₂ (minutes).

Side air permeation amount (mL/min/kPa)={(20−19)/101.3×V₁}/(T₂−T₁)/20 (3)

The side air permeation amount of the substrate 2 in the state of the double-sided adhesive sheet 1 can be evaluated in the same manner as above by using the adhesive agent layers 3A and 3B included in the double-sided adhesive sheet 1 instead of the double-sided adhesive tapes 51 (in other words, by cutting out the double-sided adhesive sheet 1 which is the laminate of the substrate 2 and the adhesive agent layers 3A and 3B). The cutting-out is preferably performed while avoiding the end portions of the double-sided adhesive sheet 1.

A deformation ratio DR₃₀ in the thickness direction of the substrate 2 when the substrate 2 is compressed in the thickness direction at a pressure of 30 MPa may be 60% or less. The upper limit of the deformation ratio DR₃₀ may be 59% or less, 57% or less, 55% or less, 53% or less, 51% or less, or even 50% or less. The lower limit of the deformation ratio DR₃₀ is, for example, 0.1% or more. The pressure of 30 MPa corresponds to, for example, the pressure applied when punching out the double-sided adhesive sheet 1 and shaping the double-sided adhesive sheet 1 into the adhesive layer 13 of the cover member. The deformation ratio DR₃₀ of the substrate 2 being in the above range can contribute to, for example, suppressing deformation of the double-sided adhesive sheet 1 and the adhesive layer 13 due to punching. The adhesive layer 13 whose deformation is suppressed can contribute to, for example, ensuring a side air permeation amount as the cover member 11. In addition, the adhesive layer 13 whose deformation is suppressed is suitable, for example, for reducing the area of the adhesive layer 13 in the cover member 11 and for use for the cover sheet 12 which is relatively susceptible to strain, such as a glass sheet.

The deformation ratio DR₃₀ can be evaluated as follows. The substrate 2 to be evaluated is cut out into a circular shape having a diameter of 7 mm to obtain a test piece. A cylindrical pressing element having a diameter larger than that of the test piece (for example, 13 mm) is attached to a hand press provided with a load cell (for example, CMH-003, manufactured by FUJI CONTROLS CO., LTD.), and the test piece is hand-pressed in the thickness direction thereof at a load of 1.15 kN (equivalent to a pressure of 30 MPa to the test piece) for at least 10 seconds. The hand-pressing is performed such that the entire test piece is covered with the end face of the pressing element. The deformation ratio DR₃₀ is calculated using the following equation (4) from a thickness t₀ of the test piece before hand-pressing and a thickness t₁ of the test piece after hand-pressing. The thicknesses t₀ and t₁ are measured by a dial gauge. The evaluation is conducted at room temperature. The deformation ratio DR₃₀ of the substrate 2 in the state of the double-sided adhesive sheet 1 can be obtained, for example, by the above evaluation for the substrate 2 from which the adhesive agent layer 3 is removed by a method such as dissolution.

Deformation ratio DR₃₀(%)=(t₀−t₁)/t₀×100 (4)

A deformation ratio DR_{0.5} in the thickness direction of the substrate 2 when the substrate 2 is compressed in the thickness direction at a pressure of 0.5 MPa may be 20% or less. The upper limit of the deformation ratio DR_{0.5} may be 18% or less, 16% or less, 15% or less, 13% or less, 10% or less, or even 8% or less. The lower limit of the deformation ratio DR_{0.5} is, for example, 0% or more, and may be 0.1% or more. The pressure of 0.5 MPa corresponds to, for example, the pressure applied to the cover member 11 when the cover member 11 is placed on the placement face. The deformation ratio DR_{0.5} of the substrate 2 being in the above range can contribute to, for example, suppressing deformation of the cover member 11 when the cover member 11 is placed on the placement face. The cover member 11 whose deformation is suppressed when the cover member 11 is placed is suitable, for example, for ensuring a side air permeation amount. In addition, the cover member 11 whose deformation is suppressed when the cover member 11 is placed is suitable, for example, for use for the cover sheet 12 which is relatively susceptible to strain, such as a glass sheet. The deformation ratio DR_{0.5} can be evaluated in the same manner as the deformation ratio DR₃0, except that the load applied to the test piece when the test piece is hand-pressed is changed to 20 N.

The rate of change (TR) in the thickness of the substrate 2 due to punching may be 75% or less. The upper limit of the rate of change TR may be 71% or less, 65% or less, 60% or less, 55% or less, or even 50% or less. The lower limit of the rate of change TR is, for example, 0.1% or more. The rate of change TR of the substrate 2 being in the above range can contribute to, for example, suppressing deformation of the double-sided adhesive sheet 1 and the adhesive layer 13 due to punching.

The rate of change TR can be evaluated as follows. A double-sided adhesive tape having the same shape as the substrate 2 to be evaluated is attached to each of both faces of the substrate 2. The double-sided adhesive tape is attached to each face of the substrate 2 such that the outer peripheries of the substrate 2 and the double-sided adhesive tape are aligned with each other. As each double-sided adhesive tape, a tape that itself has no air permeability in the lateral direction thereof and has sufficient adhesiveness to prevent the tape from peeling off from the substrate 2 during punching and when the rate of change TR is evaluated can be selected. The double-sided adhesive tape may be a tape unprovided with a substrate. Next, the substrate 2 to which the double-sided adhesive tapes are attached is punched out into a ring or frame shape having an area of 1 to 3500 mm². The outer shape and the inner shape of the ring shape are circles. The outer shape and the inner shape of the frame shape are both squares. The widths of the ring and frame shapes are constant in the circumferential direction. The punching is performed using a pinnacle die in a servo press machine. Next, the punched substrate 2 is cut in the thickness direction along a cutting plane passing through the center when viewed in a direction perpendicular to a principal surface of the substrate 2 (the center of the circle or square). The cutting is performed using a microtome, a feather blade, or the like in a state where the substrate 2 to be evaluated is frozen with liquid nitrogen. The freezing with liquid nitrogen is intended to suppress further pore deformation when obtaining a cut surface. Next, an enlarged image of the cut surface is obtained by a magnification observation method with a SEM or the like. The magnification of the enlarged image is preferably 100 to 500 times. Next, based on the obtained enlarged image, a thickness t₄ at the end portion of the substrate 2 (the average of the thicknesses at the end portion at four locations on the outer periphery and the inner periphery) and a thickness t₃ at the midpoint between the outer periphery and the inner periphery of the substrate 2 (since there are two midpoints in the enlarged image, the average of the thicknesses at these two midpoints) are obtained. The end portion at which the thickness t₄ is obtained corresponds to a portion of the substrate 2 that is mainly affected by the pressure during punching. Meanwhile, a portion around the midpoint at which the thickness t₃ is measured corresponds to a portion that is almost not affected by the pressure during punching. The rate of change TR is calculated using the following formula (5) from the thicknesses t₃ and t₄. The rate of change TR of the substrate 2 in the state of the double-sided adhesive sheet 1 can be evaluated by punching out the double-sided adhesive sheet 1.

Rate of change TR=(t₃−t₄)/t₃×100 (5)

The substrate 2 in a state of being included in the cover member 11 typically has undergone punching. From this viewpoint, a membrane thickness ratio given by the following equation (6) using a thickness t₆ at the end portion and a thickness t₅ at the midpoint of the substrate 2 in a state of being included in the cover member 11 may be 75% or less, 71% or less, 65% or less, 60% or less, 55% or less, or even 50% or less. The lower limit of the membrane thickness ratio is, for example, 0.1% or more.

Membrane thickness ratio=(t₅−t₆)/t₅×100 (6)

The method for obtaining the thicknesses t₅ and t₆ will be described with reference to FIG. 4. In FIG. 4, the substrate 2 included in the cover member 11 of FIG. 1B is depicted. First, the substrate 2 is cut in the thickness direction along a cutting line 71 passing through a center of gravity O when viewed in the direction perpendicular to the principal surface of the substrate 2. As the cutting line 71, a line segment Sₘᵢₙ having a shortest distance L1 between the outer peripheries of the substrate 2 is selected from among the line segments passing through the center of gravity O. The cutting is performed using a microtome, a feather blade, or the like in a state where the substrate 2 or a member including the substrate 2 (the double-sided adhesive sheet 1, the cover member 11, etc.) is frozen with liquid nitrogen. Next, an enlarged image of the cut surface is obtained by a magnification observation method with a SEM or the like. The magnification of the enlarged image is preferably 100 to 500 times. Next, based on the obtained enlarged image, the thickness t₆ at the end portion and the thickness t₅ at the midpoint of the substrate 2 are obtained. The thickness t₆ is determined as the average of the thicknesses at the points of intersection with the line segment Sₘᵢₙ when the substrate 2 is viewed in the direction perpendicular to the principal surface thereof (there are at least two points located on the outer periphery of the substrate 2, and in the example of FIG. 4, there are four points E₁ to E₄ located on the outer periphery and the inner periphery of the substrate 2). The thickness t₅ is determined as the thickness at the midpoint between the above points of intersection in the substrate 2. When there are two or more midpoints (in the example of FIG. 4, there are two midpoints, a midpoint M₁ between the points of intersection E₁ and E₂ and a midpoint M₂ between the points of intersection E₃ and E₄), the thickness t₅ can be determined as the average of the thicknesses at the respective midpoints.

The substrate 2 may have a compressive elastic modulus (compressive elastic modulus in the thickness direction) of 0.1 MPa or more. The compressive elastic modulus may be 0.3 MPa or more, 0.5 MPa or more, 0.6 MPa or more, 0.7 MPa or more, 1.0 MPa or more, 1.5 MPa or more, 2.0 MPa or more, 3.0 MPa or more, or even 3.5 MPa or more. The upper limit of the compressive elastic modulus is, for example, 50 MPa or less. The compressive elastic modulus of the substrate 2 being in the above range can contribute to, for example, suppressing deformation of the adhesive layer 13 due to punching and deformation of the cover member 11 when the cover member 11 is placed on the placement face.

The compressive elastic modulus can be evaluated by thermomechanical analysis (TMA) as follows. The substrate 2 to be evaluated is cut out, for example, into a circular shape having a diameter of 50 mm to obtain a test piece. Next, a cylindrical probe having a diameter of 1 mm is indented into the test piece in the thickness direction by TMA set to a penetration mode. The indentation is performed at room temperature at an indentation rate of 50 g/min until a load generated by the indentation reaches 700 mN. In a load-indentation amount plot where the horizontal axis indicates the load and the vertical axis indicates the indentation amount, the gradient of the plot when the load reaches 100 mN can be determined as the compressive elastic modulus. The deformation ratio DR₃₀ of the substrate 2 in the state of the double-sided adhesive sheet 1 can be obtained, for example, by the above evaluation for the substrate 2 from which the adhesive agent layer 3 is removed by a method such as dissolution.

The substrate 2 may have a side water entry pressure of, for example, 1 kPa or more. The side water entry pressure may be 5 kPa or more, 10 kPa or more, 20 kPa or more, 30 kPa or more, 40 kPa or more, 50 kPa or more, 60 kPa or more, 80 kPa or more, 100 kPa or more, or even 110 kPa or more. The upper limit of the side water entry pressure is, for example, 3000 kPa or less. The substrate 2 having a side water entry pressure in the above range can contribute to the application of the cover member 11 to, for example, usage, components, and devices that may come into contact with water.

The method for evaluating the side water entry pressure of the substrate 2 will be described with reference to FIG. 5. The substrate 2 to be evaluated is cut out into a ring shape having an outer diameter of 4.4 mm and an inner diameter of 1.9 mm. The cutting is performed at room temperature with a punching blade. Next, a double-sided adhesive tape 61 having the same size and ring shape as the cut-out substrate 2 is attached to each of both faces of the substrate 2. Each double-sided adhesive tape 61 is attached such that the outer periphery thereof and the outer periphery of the substrate 2 are aligned with each other. As each double-sided adhesive tape 61, a tape having sufficient waterproofness and adhesiveness that prevent water from penetrating the tape and prevent the tape from peeling off when the side water entry pressure is evaluated can be selected. The double-sided adhesive tape 61 may be a tape unprovided with a substrate. Next, a PET sheet 62 having a diameter of 5.4 mm is attached to the exposed surface of one double-sided adhesive tape 61 to obtain a test piece 63. The PET sheet 62 is attached so as to completely cover the one double-sided adhesive tape 61. As the PET sheet 62, a sheet that prevents water from penetrating the sheet in the thickness direction and the lateral direction thereof and does not deform significantly when the side water entry pressure is evaluated (for example, a sheet having a thickness of 100 μm) can be selected.

Next, the test piece 63 is fixed to an evaluation plate 64 via the other double-sided adhesive tape 61. The plate 64 is provided with an opening 65 (having a circular cross-sectional shape with a diameter of 1.0 mm). The test piece 63 is fixed to the plate 64 such that water can flow between the inner space of the substrate 2 and the double-sided adhesive tape 61, which have a ring shape, and the opening 65. The test piece 63 may be fixed such that the entire opening 65 is included in the inner space of the substrate 2 and the double-sided adhesive tape 61 when viewed in a direction perpendicular to a surface of the plate 64 to which the test piece 63 is fixed. The plate 64 is formed from a metal such as stainless steel, for example. It is made possible to supply water to the inner space of the substrate 2 and the double-sided adhesive tape 61 via the opening 65 of the plate 64. In addition, it is made possible to measure the pressure of the water to be supplied. Water is supplied to the above inner space (reference character 66), the pressure of the water to be supplied is increased at a rate of 5 kPa/second, and the pressure when the water seeps out at at least one location on the outer periphery of the substrate 2 can be determined as the side water entry pressure of the substrate 2. The measurement is performed at room temperature. The side water entry pressure of the substrate 2 in the state of the double-sided adhesive sheet 1 can be evaluated in the same manner as above by using the adhesive agent layers 3A and 3B included in the double-sided adhesive sheet 1 instead of the double-sided adhesive tape 61 (in other words, by cutting out the double-sided adhesive sheet 1 which is the laminate of the substrate 2 and the adhesive agent layers 3A and 3B). The cutting-out is preferably performed while avoiding the end portions of the double-sided adhesive sheet 1.

The substrate 2 may have a side air permeation amount of 0.1 mL/min/kPa or more and a side water entry pressure of 35 kPa or more, 40 kPa or more, 45 kPa or more, or even 50 kPa or more.

The substrate 2 may have a side hardness of 0.1 to 5 MPa. The side hardness of the substrate 2 being in the above range can contribute to, for example, suppressing deformation of the adhesive layer 13 due to punching and deformation of the cover member 11 when the cover member 11 is placed on the placement face.

The side hardness of the substrate 2 can be evaluated by the following nanoindentation test on the side surface of the substrate 2. A double-sided adhesive tape is attached to each of both faces of the substrate 2 to be evaluated. As each double-sided adhesive tape, a tape that can suppress bending of the substrate 2 when the side hardness is evaluated can be selected. Next, the side surface to be evaluated is smoothed using an ultramicrotome in a state where the laminate of the substrate 2 and the pair of adhesive tapes sandwiching the substrate 2 is frozen with liquid nitrogen. The nanoindentation test is performed on the smoothed surface to be evaluated under the following conditions to obtain a maximum load Pₘₐₓ at the time of indentation to a depth of 1 μm, and the side hardness is calculated by dividing the maximum load Pₘₐₓ by a projected area Ac of an indenter on the surface to be evaluated. The evaluation is conducted at room temperature. The side hardness of the substrate 2 in the state of the double-sided adhesive sheet 1 can be evaluated in the same manner as above, for example, by using the adhesive agent layer 3 included in the double-sided adhesive sheet 1 instead of the double-sided adhesive tape.

### [Test Conditions]

Device: A known nanoindentation device can be used. For example, TriboIndenter, manufactured by Hysitron Inc.
Indenter: Triangular pyramid type (for example, manufactured by Berkovich)
Evaluation mode: Single indentation
Indentation depth: 1 μm

The substrate 2 may have a cohesive force (cohesive force in the thickness direction) of 0.3 to 30 N/20 mm. The cohesive force of the substrate 2 being in the above range can contribute to, for example, suppressing damage to the cover member 11 at the time of peeling of the cover member 11 which is placed on the placement face only during a specific treatment and is peeled off after the treatment. The cohesive force of the substrate 2 can be determined as the maximum value of stress measured in a tensile test in which a test piece is prepared by attaching a double-sided adhesive tape to each of both faces of the substrate 2 and the respective attached double-sided adhesive tapes are grasped and peeled at 180° to cohesively break the substrate 2. The width of the substrate 2 and the double-sided adhesive tapes in the test piece is set to 20 mm. The peeling speed in the tensile test is set to 300 mm/min. As each double-sided adhesive tape, a tape having sufficient strength and adhesiveness that prevent the tape from breaking in the tensile test and from peeling off from the substrate 2 can be selected. The evaluation is conducted at room temperature.

The first adhesive agent layer 3A and the second adhesive agent layer 3B are typically layers formed from an adhesive agent composition. The adhesive agent composition may be a pressure-sensitive adhesive agent composition. In other words, at least one selected from the first adhesive agent layer 3A and the second adhesive agent layer 3B may be a pressure-sensitive adhesive agent layer. With a thermosetting or photosensitive adhesive agent composition (for example, epoxy or benzocyclobutene (BCB) adhesive agent composition disclosed in Patent Literature 1), usually, when an adhesive agent layer is formed adjacent to the substrate 2 in order to form the adhesive agent layer by applying a low-viscosity solution, the adhesive agent easily permeates the interior of the substrate 2. Meanwhile, the pressure-sensitive adhesive agent composition usually has a higher viscosity than a thermosetting or photosensitive adhesive agent composition, and thus is suitable for suppressing permeation of the adhesive agent to the substrate 2.

The adhesive agent composition may be a thermosetting adhesive agent composition such as epoxy and phenolic adhesive agent compositions. In other words, at least one selected from the first adhesive agent layer 3A and the second adhesive agent layer 3B may be a thermosetting adhesive agent layer. The adhesive agent layer 3 formed from a thermosetting adhesive agent composition generally has excellent heat resistance. However, in consideration of suppressing permeation to the substrate 2, the thermosetting adhesive agent composition may have a storage modulus of 1×10⁵ Pa or more at 130 to 170° C., and may have a storage modulus of 5×10⁵ Pa or more at 250° C. after thermal curing. The magnitude of the storage modulus can contribute to suppressing flowability. 130 to 170° C. corresponds to the general temperature at which thermal curing of the thermosetting adhesive agent composition is caused to begin to proceed. The storage modulus at 130 to 170° C. is determined as a storage modulus at 130 to 170° C. evaluated with a film (22.5 mm in length and 10 mm in width) of the adhesive agent composition as a test piece while heating the test piece at a temperature increase rate of 10° C./min, for example, from 0° C. to 260° C., using a forced vibration viscoelastic analyzer for solids. The direction of measurement (direction of vibration) of the test piece is set to a longitudinal direction of the test piece, and the vibration frequency is set to 1 Hz. The storage modulus at 250° C. (after curing) can be evaluated by conducting the same test on the test piece after the film of the adhesive agent composition is thermally cured.

Examples of the adhesive agent composition include acrylic, silicone, urethane, epoxy, and rubber adhesive agent compositions. When it is assumed that the double-sided adhesive sheet 1 and a member including the double-sided adhesive sheet 1 such as a cover member are exposed to high temperatures (for example, 200° C. corresponding to reflow soldering, or even 250° C.), an acrylic or silicone adhesive agent composition having excellent heat resistance may be selected. In other words, at least one selected from the first adhesive agent layer 3A and the second adhesive agent layer 3B may be an acrylic adhesive agent layer or a silicone adhesive agent layer. In addition, the types of the adhesive agent compositions of the first adhesive agent layer 3A and the second adhesive agent layer 3B may be different from each other.

The acrylic adhesive agent is, for example, an adhesive agent disclosed in JP 2005-105212 A. The silicone adhesive agent is, for example, an adhesive agent disclosed in JP 2003-313516 A (including those disclosed as comparative examples).

The adhesive strength of the adhesive agent layer 3, is, for example, 0.5 to 30 N/20 mm, and may be 0.7 to 20 N/20 mm or even 1 to 15 N/20 mm, as a peeling adhesive strength obtained by the 180° peeling adhesive strength test (Method 1) specified in the Japanese Industrial Standards (hereinafter referred to as JIS) Z0237: 2009. The adhesive agent layer 3 may have a decrease rate of adhesive strength (based on pre-test adhesive strength) of 60% or less, 50% or less, or even 40% or less before and after a heat resistance test at a peak temperature of 250° C. assuming reflow soldering. The adhesive agent layer 3 satisfying the above range of the decrease rate is suitable for use in the cover member 11 which is subjected to a high-temperature treatment such as reflow soldering.

The first adhesive agent layer 3A and the second adhesive agent layer 3B may have different characteristics such as adhesive strength. For example, the adhesive strength of the second adhesive agent layer 3B which can be exposed when a cover member is made may have a relatively low adhesive strength in consideration of re-peeling of the cover member. The double-sided adhesive sheet 1 having one adhesive face having re-peelability is suitable, for example, for use in the cover member 11 which is placed on the placement face only during a specific treatment and is peeled off after the treatment.

In consideration of re-peelability, the adhesive strength of the adhesive agent layer 3 is, for example, 0.05 to 5.0 N/20 mm, and may be 0.08 to 2.0 N/20 mm or even 1.5 to 2.0 N/20 mm, as the above peeling adhesive strength.

The thickness of the adhesive agent layer 3 is, for example, 2 to 150 μm, and may be 5 to 100 μm or even 7 to 90 μm.

The thickness of the double-sided adhesive sheet 1 is, for example, 10 to 300 μm, and may be 20 to 200 μm or even 20 to 150 μm.

The double-sided adhesive sheet 1 may include a further member other than the substrate 2, the first adhesive agent layer 3A, and the second adhesive agent layer 3B as long as the substrate 2 has a porous structure and the above relationships for the porosity and the average pore diameter LA are satisfied in the substrate 2.

An example of the further member is a release sheet (release liner) covering the adhesive agent layer 3. The release sheet may be placed so as to cover at least one selected from the adhesive agent layers 3A and 3B. The release sheet can be peeled off when the double-sided adhesive sheet 1 is used. As the release sheet, a release sheet that is included in a known adhesive sheet can be used. The double-sided adhesive sheet 1 in the form of a strip may be wound in a state of including the release sheet.

The double-sided adhesive sheet 1 can be manufactured, for example, by applying an adhesive agent composition to each of both faces of the substrate 2, and then drying and/or curing the applied adhesive agent composition. However, the method for manufacturing the double-sided adhesive sheet 1 is not limited to the above example.

The cover member 11 may have re-peelability. The cover member 11 having re-peelability is suitable, for example, for use in applications where the cover member 11 is placed on the placement face only during a specific treatment and is peeled off from the placement face after the treatment, or applications where the cover member 11 is placed on the placement face only during storage, transportation, or inspection (optical inspection, image inspection, etc.) and is peeled off from the placement face when in use, after transportation, or after inspection. Re-peelability means the property that the cover member 11 can be peeled off from the placement face without damaging or destroying the placement face, the member having the placement face, the cover member 11, and the member included in the cover member 11. Examples of the specific treatment include high-temperature treatments such as reflow soldering.

In one example of the cover member 11 having re-peelability, the adhesive layer 13 has re-peelability from the placement face. The adhesive layer 13 having re-peelability may have an adhesive strength of 0.05 to 5.0 N/20 mm, 0.08 to 2.0 N/20 mm, or even 1.5 to 2.0 N/20 mm as the above peeling adhesive strength.

In one example of the adhesive layer 13 having re-peelability, the adhesive agent layer 3 included in the double-sided adhesive sheet 1 included in the adhesive layer 13 (typically, the second adhesive agent layer 3B which can be joined to the placement face) has re-peelability.

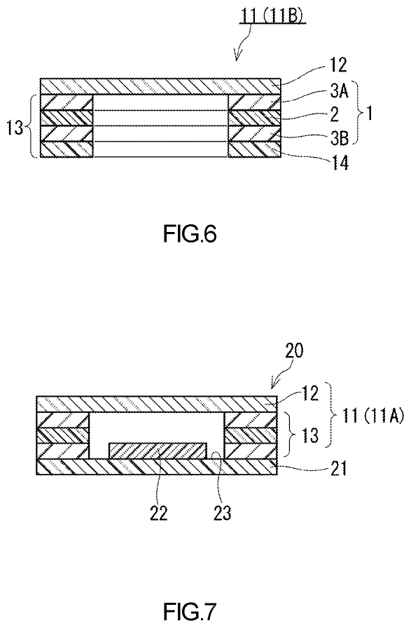

In one example of the adhesive layer 13 having re-peelability, the adhesive layer 13 further includes a re-peelable adhesive agent layer. FIG. 6 shows an example of the cover member 11 in which the adhesive layer 13 further includes a re-peelable adhesive agent layer. The adhesive layer 13 of the cover member 11 (11B) of FIG. 6 includes the double-sided adhesive sheet 1 and a re-peelable adhesive agent layer 14. The re-peelable adhesive agent layer 14 is exposed. The cover member 11B can be fixed to the placement face via the re-peelable adhesive agent layer 14.

The re-peelable adhesive agent layer 14 may have an adhesive strength of 0.05 to 5.0 N/20 mm, 0.08 to 2.0 N/20 mm, or even 1.5 to 2.0 N/20 mm as the above peeling adhesive strength. As the re-peelable adhesive agent layer 14, a known adhesive agent layer having weak or very weak adhesiveness can be used. The re-peelable adhesive agent layer 14 may be an adhesive sheet including a substrate and an adhesive agent layer joined to the substrate, and the adhesive sheet may be a single-sided adhesive sheet or a double-sided adhesive sheet.

The adhesive layer 13 may include a member other than those described above.

The adhesive layer 13 of the cover member 11A of FIG. 1A and FIG. 1B has a shape corresponding to a peripheral portion of the cover sheet 12 when viewed in a direction perpendicular to a principal surface of the cover sheet 12, and is joined to the peripheral portion. More specifically, the shape of the adhesive layer 13 is a frame shape corresponding to the peripheral portion of the cover sheet 12 which is rectangular when viewed in the direction perpendicular to the principal surface of the cover sheet 12. However, the shape and the placement of the adhesive layer 13 are not limited to the above example. In addition, the surface on the adhesive layer 13 side of the cover sheet 12 is exposed in a region A which is not in contact with the adhesive layer 13. For example, when the cover sheet 12 is an optically transparent sheet, the cover member 11A can transmit light mainly in the region A.

The area of the region A may be 3000 mm² or less, 2000 mm² or less, 1000 mm² or less, 500 mm² or less, 300 mm² or less, 100 mm² or less, 50 mm² or less, 30 mm² or less, 10 mm² or less, or even 5 mm² or less. The lower limit of the area of the region A is, for example, 1 mm² or more, and may be 3 mm² or more or even 5 mm² or more. The cover member 11 in which the area of the region A is in the above range is particularly suitable, for example, for forming a semiconductor device package.

The cover member 11 may be a member that is fixed to the placement face without being re-peeled off after being placed on the placement face, or a member that is re-peeled off after being placed on the placement face. The cover member of the present embodiment is suitable for being either of these members.

The cover sheet 12 may have air permeability in the thickness direction thereof, or may have no air permeability in the thickness direction thereof. In the cover member 11, even when the cover sheet 12 has no air permeability in the thickness direction thereof, the substrate 2 of the double-sided adhesive sheet 1 can contribute to air permeability between the space surrounded by the cover member 11 and the placement face and the outside. In the present specification, having no air permeability in the thickness direction means that the gas permeability (hereinafter referred to as “Gurley air permeability”) in the thickness direction obtained according to Method B (Gurley method) of gas permeability measurement specified in JIS L1096 is 10000 seconds/100 mL or more.

Examples of the material contained in the cover sheet 12 include a metal, a metal compound, a resin, and a composite material thereof.

Examples of the resin, the metal, and the metal compound that can be contained in the cover sheet 12 are the same as the examples of the resin, the metal, and the metal compound that can be contained in the substrate 2, respectively.

The cover sheet 12 may contain a heat-resistant material. The cover sheet 12 containing a heat-resistant material is suitable, for example, for use in the cover member 11 which is subjected to a high-temperature treatment such as reflow soldering. Examples of the heat-resistant material that can be contained in the cover sheet 12 are the same as the examples of the heat-resistant material that can be contained in the substrate 2.

The cover sheet 12 may contain at least one selected from a heat-resistant material which is a resin (heat-resistant resin), and glass. The heat-resistant resin may be at least one selected from a silicone resin, a fluorine resin, and polyimide, or may be polyimide.

The cover sheet 12 may be an optically transparent sheet. The cover sheet 12 being an optically transparent sheet is particularly suitable, for example, for covering an optical semiconductor device. In the present specification, optically transparent means that a total light transmittance in the thickness direction as defined in JIS K7375 is 80% or more, preferably 85% or more, more preferably 90% or more, and further preferably 95% or more when the thickness is 50 μm.

The cover sheet 12 which is an optically transparent sheet contains, for example, at least one selected from a transparent resin and glass. Examples of the transparent resin include polyimide, polyethylene terephthalate, and an acrylic resin. The cover sheet 12 may be a sheet that contains a heat-resistant material and is optically transparent. An example of the sheet that contains a heat-resistant material and is optically transparent is a polyimide sheet.

The cover sheet 12 may have a function other than preventing passage of foreign matter, for example, an optical function. Examples of the cover sheet 12 having an optical function include optical sheets such as an optical lens. Examples of the optical sheets include various optical members such as a lens, a phase difference film, a polarizing film, a reflecting film, and an antireflection film.

The cover sheet 12 may be a single layer or may have a multilayer structure of two or more layers.

The thickness of the cover sheet 12 is, for example, 1 to 2000 μm.

The shape of the cover sheet 12 is, for example, a polygon such as a square or a rectangle, a circle, or an ellipse when viewed in the direction perpendicular to the principal surface of the cover sheet 12. The polygon may be a regular polygon. Each corner of the polygon may be rounded. However, the shape of the cover sheet 12 is not limited to the above examples.

The area of the cover sheet 12 may be 3500 mm² or less, 3000 mm² or less, 2000 mm² or less, 1000 mm² or less, 500 mm² or less, 300 mm² or less, 100 mm² or less, 50 mm² or less, 30 mm² or less, 10 mm² or less, or even 5 mm² or less. The lower limit of the area is, for example, 1 mm² or more, and may be 3 mm² or more or even 5 mm² or more. The cover member 11 in which the area of the cover sheet 12 is in the above range is particularly suitable, for example, for forming a semiconductor device package.

The thickness of the cover member 11 is, for example, 0.03 to 3 mm, and may be 0.05 to 2 mm.

The shape of the cover member 11 is, for example, a polygon such as a square or a rectangle, a circle, or an ellipse when viewed in the direction perpendicular to the principal surface of the cover sheet 12. The polygon may be a regular polygon. Each corner of the polygon may be rounded. However, the shape of the cover member 11 is not limited to the above examples.

The area of the cover member 11 may be 3500 mm² or less, 3000 mm² or less, 2000 mm² or less, 1000 mm² or less, 500 mm² or less, 300 mm² or less, 100 mm² or less, 50 mm² or less, 30 mm² or less, 10 mm² or less, or even 5 mm² or less. The lower limit of the area is, for example, 1 mm² or more, and may be 3 mm² or more or even 5 mm² or more. The cover member 11 having an area in the above range is particularly suitable, for example, for forming a semiconductor device package.

The cover member 11 may include any member other than those described above.

The cover member 11 may be placed so as to cover a semiconductor device with a face of a substrate on which the semiconductor device is mounted being a placement face, and may be used for forming a semiconductor device package in which the semiconductor device is housed in an inner space of the package by placing cover member 11 on the placement face. In other words, the cover member 11 may be for a semiconductor device package. However, the use of the cover member 11 is not limited to the use for a semiconductor device package.

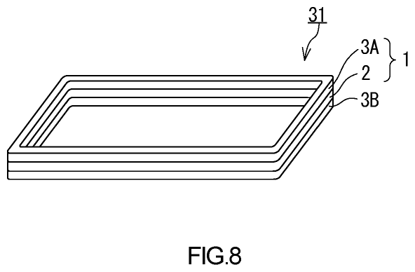

FIG. 7 shows an example of a semiconductor device package in which the cover member of the present embodiment is used. A semiconductor device package 20 of FIG. 7 includes a substrate 21, a semiconductor device 22 placed on the substrate 21, and the cover member 11 (11A). The cover member 11 is fixed on the substrate 21 so as to cover the semiconductor device 22 (in other words, with the semiconductor device 22 as an object to be covered) with a face 23 of the substrate 21 on which the semiconductor device 22 is mounted, as a placement face. The semiconductor device 22 is housed in an inner space formed by the substrate 21 and the cover member 11. The semiconductor device package 20 can be manufactured by a known method using the substrate 21, the semiconductor device 22, and the cover member 11.

The cover member 11 can be manufactured, for example, by shaping and stacking the cover sheet 12 and the adhesive layer 13. An example of the shaping is punching. However, the method of the shaping is not limited to the above example.

An example of the substrate 21 is a semiconductor substrate. The substrate 21 may be a circuit board on which circuits are formed. Examples of the semiconductor device 22 include optical semiconductor devices such as CCD, CMOS, an infrared (IR) sensor element, a TOF sensor element, a LiDAR sensor element, and a laser element, and acceleration sensors. The semiconductor device 22 may be a micro electro mechanical system (MEMS). However, the substrate 21 and the semiconductor device 22 are not limited to the above examples.

The cover member 11 can be supplied in a state of being placed on a release sheet. A plurality of cover members 11 may be placed on the release sheet. The adhesive layer (for example, the adhesive layer 13) included in the cover member 11 may be used for the placement on the release sheet. In addition, a weak adhesive layer may be provided on a face of the release sheet on which the cover member 11 is to be placed, and the cover member 11 may be placed via the weak adhesive layer. A member supplying sheet in which a release sheet is a substrate sheet will be described later.

### [Double-Sided Adhesive Sheet]

FIG. 2 shows an example of a double-sided adhesive sheet of the present embodiment. The double-sided adhesive sheet 1 of FIG. 2 has a structure in which the first adhesive agent layer 3A, the substrate 2, and the second adhesive agent layer 3B are laminated in this order. The substrate 2 has a porous structure. The porosity of the substrate 2 is 30% or more. (1) When the porosity of the substrate 2 is 30% or more and 50% or less, the average pore diameter (average pore diameter LA) of the substrate 2 is 10 μm or more, and (2) when the porosity of the substrate 2 is more than 50%, the average pore diameter LA is 0.05 μm or more.

The double-sided adhesive sheet of the present embodiment can have the characteristics and the structure of the substrate 2 and/or the double-sided adhesive sheet 1 described above in the description of the cover member 11, including the preferred modes. For example, the double-sided adhesive sheet of the present embodiment may have the characteristics described above in the description of the substrate 2 and in the numerical ranges indicated in this description. As a more specific example, the double-sided adhesive sheet of the present embodiment may have at least one selected from the side air permeation amount, the deformation ratio DR₃₀, the deformation ratio DR_{0.5}, the rate of change TR, the compressive elastic modulus, the side water entry pressure, and the cohesive force in the numerical ranges above.

Examples of the shape of the double-sided adhesive sheet 1 include a polygon such as a square or a rectangle, a circle, an ellipse, and a strip shape. The polygon may be a regular polygon. Each corner of the polygon may be rounded. The double-sided adhesive sheet 1 in the form of a strip may be in the form of a roll wound around a winding core. However, the shape of the double-sided adhesive sheet 1 is not limited to the above examples.

The double-sided adhesive sheet 1 may include a further member other than the substrate 2, the first adhesive agent layer 3A, and the second adhesive agent layer 3B as long as the substrate 2 has a porous structure and the above relationships for the porosity and the average pore diameter LA are satisfied in the substrate 2.

An example of the further member is a release sheet (release liner) covering the adhesive agent layer 3. The release sheet may be placed so as to cover at least one selected from the first adhesive agent layer 3A and the second adhesive agent layer 3B. The release sheet can be peeled off when the double-sided adhesive sheet 1 is used. As the release sheet, a release sheet that is included in a known adhesive sheet can be used. The double-sided adhesive sheet 1 in the form of a strip may be wound in a state of including the release sheet.

### [Seal Member]

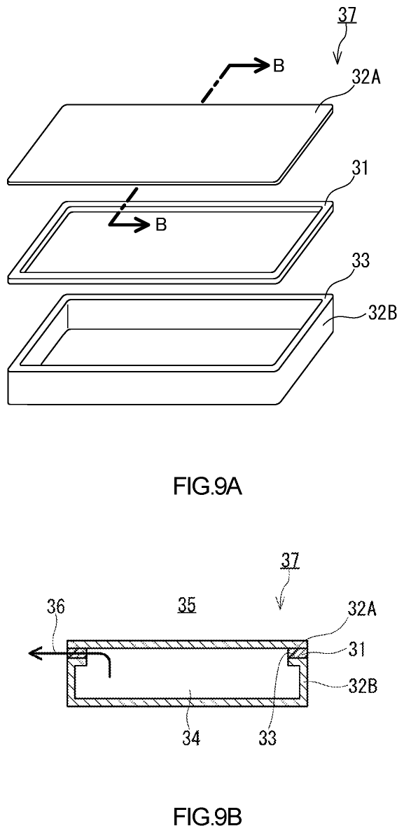

With the double-sided adhesive sheet of the present embodiment, it is also possible to obtain a seal member suitable for ensuring air permeability while preventing passage of foreign matter. FIG. 8 shows an example of a seal member of the present embodiment, and FIG. 9A and FIG. 9B each show an example of the usage thereof. FIG. 9A is an exploded perspective view showing an example of an electronic device 37 in which the seal member of the present embodiment is incorporated. FIG. 9B is a cross-sectional view showing a cross-section B-B in the electronic device 37 of FIG. 9A. A seal member 31 of FIG. 8, FIG. 9A, and FIG. 9B is a member that is placed between a first component 32A and a second component 32B when the first component 32A and the second component 32B are joined, and prevents passage of foreign matter between an inner space 34 surrounded by the first component 32A and the second component 32B joined together and an outside 35. The seal member 31 has an air flow path 36 between the inner space 34 and the outside 35. The seal member 31 also includes the double-sided adhesive sheet 1 of the present embodiment. The substrate 2 of the double-sided adhesive sheet 1 is included in the air flow path 36. In the example of FIG. 9A and FIG. 9B, the air permeability between the inner space 34 and the outside 35 may be ensured mainly by the substrate 2.

The seal member 31 of FIG. 9A and FIG. 9B has a shape corresponding to a peripheral portion of the first component 32A, more specifically, a frame shape, when viewed in a direction perpendicular to a principal surface of the first component 32A. In addition, the seal member 31 is placed between the first component 32A and a placement face 33 provided on a peripheral portion of the second component 32B when viewed perpendicular to the above principal surface. The seal member 31 may have a ring shape or a frame shape. However, the shape and the placement of the seal member 31 are not limited to the above example.

In the seal member 31 having a ring shape or a frame shape, the area of a region surrounded by the seal member 31 may be 50 cm² or more, 60 cm² or more, 70 cm² or more, or even 100 cm² or more. The upper limit of the area is, for example, 60000 cm² or less.

The width of the seal member 31 may be 5 mm or less, 4 mm or less, 3 mm or less, 2 mm or less, or even 1.5 mm or less. In this case, the area of the region surrounded by the seal member 31 having a ring shape or a frame shape may be in the range described above as an example.

In the electronic device 37, the seal member 31 (the first adhesive agent layer 3A and/or the second adhesive agent layer 3B thereof) may be used to join the first component 32A and the second component 32B.

Examples of the electronic device 37 include portable electronic devices such as a smartphone and a smartwatch, and industrial electronic devices such as an in-vehicle ECU (Electrical Control Unit). Examples of the first component 32A include sheets such as a resin sheet, a metal sheet, and a glass sheet, and image forming panels such as a liquid crystal panel and an organic EL panel. An example of the second component 32B is a housing of the electronic device 37 (or a part of the housing). However, the first component, the second component, and the electronic device are not limited to the above examples. Both the first component and the second component may be parts of the housing of the electronic device, and the housing of the electronic device may be formed by joining both components.

The seal member 31 may include members other than the double-sided adhesive sheet 1 if necessary.

The seal member 31 can be manufactured, for example, by shaping the double-sided adhesive sheet 1.

### [Member Supplying Sheet]

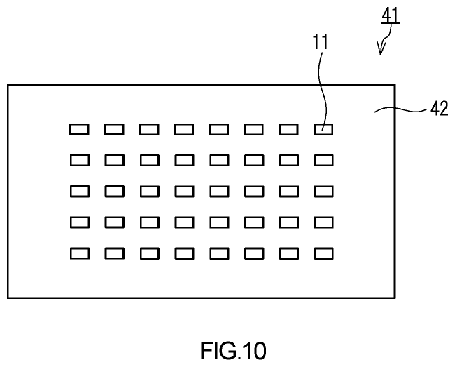

FIG. 10 shows an example of a member supplying sheet of the present embodiment. A member supplying sheet 41 of FIG. 10 includes a substrate sheet 42 and a plurality of cover members 11 placed on the substrate sheet 42. The member supplying sheet 41 is a sheet for supplying the cover member 11. The member supplying sheet 41 is suitable, for example, for efficiently supplying the cover member 11.

In the example of FIG. 10, two or more cover members 11 are placed on the substrate sheet 42. The number of cover members 11 placed on the substrate sheet 42 may be one.

Examples of the material forming the substrate sheet 42 include paper, a metal, a resin, and a composite material thereof. Examples of the metal include stainless steel and aluminum. Examples of the resin include polyesters such as PET, and polyolefins such as polyethylene and polypropylene. However, the material forming the substrate sheet 42 is not limited to the above examples.

The cover member 11 may be placed on the substrate sheet 42 via an adhesive layer (for example, the adhesive layer 13) included in the member 11. In this case, a placement face of the substrate sheet 42 on which the cover member 11 is placed may be subjected to a release treatment for improving ease of release of the cover member 11 from the substrate sheet 42. The release treatment can be performed by a known technique.

The cover member 11 may be placed on the substrate sheet 42 via an adhesive layer, typically a weak adhesive layer, being provided on the placement face of the substrate sheet 42 on which the cover member 11 is placed.

The thickness of the substrate sheet 42 is, for example, 1 to 200 μm.

The member supplying sheet 41 and the substrate sheet 42 of FIG. 10 are in the form of a sheet. The member supplying sheet 41 and the substrate sheet 42 may be in the form of a strip. The member supplying sheet 41 in the form of a strip may be in the form of a roll wound around a winding core.

The member supplying sheet 41 can be manufactured by placing the cover members 11 on the substrate sheet 42.

The member placed on the substrate sheet 42 may be the seal member 31 instead of the cover member 11. The member supplying sheet 41 in which the seal member 31 is placed is suitable, for example, for efficiently supplying the seal member 31.

### Examples

Hereinafter, the present invention will be described more specifically by way of examples. The present invention is not limited to the modes shown in the examples below.

Evaluation methods for substrates prepared in the examples will be described.

### [Thickness]

The thickness of each substrate was obtained as the average of values measured by a dial-type thickness gauge (manufactured by Mitutoyo Corporation, measuring terminal diameter 0=10 mm) at three measurement points. The thicknesses t₀ and t₁ which are measured when the deformation ratios DR₃₀ and DR_{0.5} are evaluated were the averages of values measured by the dial-type thickness gauge for three samples prepared by punching out the substrate so as to have a diameter of 7 mm.

### [Porosity]

The porosity of each substrate was evaluated by the method described above. The shape of the test piece was a circular shape having a diameter of 47 mm.

### [Average Pore Diameter LA]

The average pore diameter LA of each substrate was evaluated by the method described above. The enlarged image was obtained as a SEM image for which the magnification was varied in the range of 300 to 5000 times and the area of the observation range was varied in the range of 20 to 4000 μm² according to the pore diameter. The cross-section to be observed was a cross-section viewed from the side surface in the width direction of the substrate in the form of a strip. In other words, the obtained average pore diameter is an average pore diameter evaluated from the side surface. The number of cross-sections to be observed was one. Image J was used for image analysis.

### [Side Air Permeation Amount]

The side air permeation amount of each substrate was evaluated by the method described above. A punching die having a pinnacle blade was used for cutting-out. As each double-sided adhesive tape 51, No. 5603R (a PET substrate and an acrylic adhesive agent layer) manufactured by Nitto Denko Corporation was used. As the PET sheet 52, LUMIRROR (thickness: 75 μm) manufactured by Toray Industries, Inc., was used. The shape of the cross-section of the opening 55 in the evaluation jig was a circular shape having a diameter of 1 mm. The volume V₁ of the space 57 formed inside the evaluation jig was 70 mL.

[Deformation Ratios DR₃₀ and DR_{0.5}]

The deformation ratios DR₃₀ and DR_{0.5} of each substrate were evaluated by the method described above. CMH-003 manufactured by FUJI CONTROLS CO., LTD., was used as the hand press provided with a load cell. The diameter of the pressing element was 130 mm. The time of the hand-pressing was 10 seconds.

### [Rate of Change TR in Thickness]

The rate of change TR in the thickness of each substrate was evaluated by the method described above. The substrate was punched into a frame shape having an outer shape of a 4.4 mm square and an inner shape of a 1.9 mm square (both the outer shape and the inner shape are squares) using a punching die having a pinnacle blade. The magnification of the enlarged image was 300 times. As each double-sided adhesive tape, No. 5603R manufactured by Nitto Denko Corporation was used.

### [Compressive Elastic Modulus]

The compressive elastic modulus was evaluated by the method described above. A thermomechanical analyzer (TMA4000SA, manufactured by Bruker AXS) was used for TMA.

### [Side Water Entry Pressure]

The side water entry pressure was evaluated by the method described above. A punching die having a pinnacle blade was used for cutting-out. As each double-sided adhesive tape 61, No. 5603R manufactured by Nitto Denko Corporation was used. As the PET sheet 62, LUMIRROR (thickness: 75 μm) manufactured by Toray Industries, Inc., was used.

### Example 1

A stretched porous PTFE sheet (NTF820A, manufactured by Nitto Denko Corporation) was prepared as a substrate of Example 1.

### Example 2

A stretched porous PTFE sheet (NTF1122, manufactured by Nitto Denko Corporation) was prepared as a substrate of Example 2.

### Example 3

A stretched porous PTFE sheet (NTF1131, manufactured by Nitto Denko Corporation) was prepared as a substrate of Example 3.

### Example 4

A stretched porous PTFE sheet (NTF8031, manufactured by Nitto Denko Corporation) was prepared as a substrate of Example 4.

### Example 5

A stretched porous PTFE sheet (NTF1133, manufactured by Nitto Denko Corporation) was prepared as a substrate of Example 5.

### Example 6

As a substrate of Example 6, a stretched porous PTFE sheet was prepared as follows. 100 parts by weight of PTFE fine powder (POLYFLON F-121, manufactured by Daikin Industries, Ltd.) and 20 parts by weight of n-dodecane (manufactured by Japan Energy Corporation) as a molding aid were uniformly mixed. The obtained mixture was compressed by a cylinder and then ram-extruded to form a sheet-shaped mixture. Next, the formed sheet-shaped mixture was rolled to a thickness of 0.8 mm by passing the mixture between a pair of metal rolls, and the molding aid was further removed by heating at 150° C. to form a strip-shaped PTFE sheet molded body. Next, the formed sheet molded body was stretched in the longitudinal direction at a stretching temperature of 300° C. and a stretching ratio of 3.5 times, then further stretched in the width direction at a stretching temperature of 150° C. and a stretching ratio of 25 times, and sintered at 400° C., which is a temperature equal to or higher than the melting point of PTFE, to obtain a stretched porous PTFE sheet.

### Example 7

A foam sheet with a density of 0.55 g/cm³ and a 15% compression load of 9 N/cm² produced using a two-component curing type liquid silicone rubber was prepared as a substrate of Example 7. The density of the above foam sheet was calculated by dividing the weight of a test piece having a size of 20 mm×20 mm by the volume of the test piece. The dimensions of the test piece for calculating the volume were measured by calipers. The compression load was measured according to the compression hardness measurement method specified in JIS K6767. It should be noted that the size of the test piece was 30 mm×30 mm, the maximum stress (N) when the test piece was compressed in the thickness direction at a compression rate of 10 mm/min until the compression ratio reached 15% was converted a value per unit area (1 cm²) of the test piece, and the converted value was defined as the 15% compression load (N/cm²).

### Example 8

An acrylic resin foam sheet (PureCell 008, manufactured by INOAC CORPORATION) was prepared as a substrate of Example 8.

### Example 9

A PET mesh sheet (T No. 420S, manufactured by Nippon Tokushu Fabric Inc.) was prepared as a substrate of Example 9.

### Example 10

An ultrahigh-molecular-weight polyethylene particle porous aggregated sheet (SUNMAP LC, manufactured by Nitto Denko Corporation) was prepared as a substrate of Example 10.

### Example 11

An ultrahigh-molecular-weight polyethylene particle porous aggregated sheet (SUNMAP FS, manufactured by Nitto Denko Corporation) was prepared as a substrate of Example 11.

### Example 12

As a substrate of Example 12, a fumed silica sheet was prepared as follows. Hydrophilic fumed silica (AEROSIL 50, manufactured by NIPPON AEROSIL CO., LTD., BET specific surface area: 50 m²/g, apparent specific gravity: 50 g/L, average particle diameter of primary particles: 40 nm, average diameter of secondary aggregates: 0.2 μm), which is an inorganic fine particle aggregate, was mixed with PTFE particles and a volatile additive using a V-type mixer to obtain a paste. As the PTFE particles, POLYFLON PTFE F-104 (average particle diameter: 550 μm) manufactured by Daikin Industries, Ltd., was used. As the volatile additive, dodecane was used. The PTFE particles were added such that the weight ratio between the PTFE particles and the inorganic fine particle aggregate was 40:60. The volatile additive was added so as to make up 62% of the total weight of the mixture. The rotation speed of the mixer was 10 rpm, the mixing time was 5 minutes, and the mixing temperature was 24° C. Next, the obtained paste was passed between a pair of rolling rolls to be molded into a substantially-elliptical mother sheet (sheet-shaped molded body) having a thickness of 3 mm, a width (short diameter) of 10 to 50 mm, and a length (long diameter) of 150 mm, and the formed mother sheet was rolled by passing this sheet again between the above rolling rolls in the same rolling direction as before, to produce a first rolled sheet. Next, the following rolling (I) to (Ill) using rolling rolls was performed in order on the first rolled sheet to obtain a sheet having a thickness of about 0.3 mm. Next, the obtained sheet was heated at 150° C. for 5 minutes to remove the volatile additive, and further sintered at 380° C. for 5 minutes to produce a fumed silica sheet which is a plate-shaped porous material having a thickness of about 0.3 mm.

Rolling (I): The first rolled sheet is folded into four, rolled by rolling rolls having a gap of 0.6 mm (first rolling), and further rolled by rolling rolls having a gap of 0.45 mm (second rolling). The folding into four, the first rolling, and the second rolling are repeated six times. The direction of rolling is the same as the direction of rolling in producing the first rolled sheet.

Rolling (II): The first rolled sheet is rotated by 90 degrees with respect to the direction of rolling in rolling (I). The rotated first rolled sheet is folded into four, rolled by rolling rolls having a gap of 0.6 mm (third rolling), and further rolled by rolling rolls having a gap of 0.45 mm (fourth rolling). The folding into four, the third rolling, and the fourth rolling are repeated twice. The direction of rolling is different by 90 degrees in the in-plane direction of the sheet from the direction of rolling in rolling (I).

Rolling (III): The first rolled sheet is rolled by rolling rolls having a gap of 0.2 mm. The direction of rolling is the same as the direction of rolling in rolling (II).

### Example 13

A fumed silica sheet which is a substrate of Example 13 was prepared in the same manner as in Example 12, except that the PTFE particles were added such that the weight ratio between the PTFE particles and the inorganic fine particle aggregate was 30:70, and the volatile additive was added so as to make up 68% of the total weight of the mixture.

### Example 14

A fumed silica sheet which is a substrate of Example 14 was prepared in the same manner as in Example 12, except that hydrophobic fumed silica (RX300, manufactured by NIPPON AEROSIL CO., LTD., BET specific surface area: 230 m²/g, apparent specific gravity: 50 g/L, average particle diameter of primary particles: 7 nm) was used as an inorganic fine particle aggregate, and after the volatile additive was removed and then sintering was performed, further rolling by rolling rolls having a gap of 0.2 mm was performed. The direction of the further rolling was the same as the direction of rolling in rolling (Ill).

### Example 15

A stretched porous PTFE sheet (NTF811A, manufactured by Nitto Denko Corporation) was prepared as a substrate of Example 15.

### Example 16

As a substrate of Example 16, a PTFE particle sintered sheet was prepared as follows. PTFE powder (POLYFLON PTFE M-12, manufactured by Daikin Industries, Ltd.) was placed in a cylindrical mold and preformed. The preforming can be performed at a temperature of 23° C. such that the density of the formed preform was 0.8 g/mL. Next, the formed preform was taken out from the mold and sintered at 350° C. for 3 hours to obtain a PTFE block having a cylindrical shape with a height of 100 mm and an outer diameter of 50 mm. Next, the obtained PTFE block was cut by a lathe to obtain a sintered sheet having a thickness of 200 μm.

### Example 17

A PTFE particle sintered sheet which is a substrate of Example 17 was prepared in the same manner as in Example 16, except that the preforming was performed such that the density of the formed preform was 0.6 g/mL.

### Comparative Example 1

A polyethylene particle porous aggregated sheet (F16CK2, manufactured by Toray BSF) was prepared as a substrate of Comparative Example 1.

### Comparative Example 2

A foam sheet with a density of 0.83 g/cm³ and a 15% compression load of 20 N/cm² produced using a two-component curing type liquid silicone rubber was prepared as a substrate of Comparative Example 2. The evaluation methods for the density and the 15% compression load are the same as for the substrate of Example 7.

### Comparative Example 3

A stretched porous PTFE sheet (NTF663, manufactured by Nitto Denko Corporation) was prepared as a substrate of Comparative Example 3.

### Comparative Example 4

As a substrate of Comparative Example 4, a composite material sheet was prepared as follows. Hydrophobic fumed silica (NY50, manufactured by NIPPON AEROSIL CO., LTD., BET specific surface area: 50 m²/g, apparent specific gravity: 60 g/L, average particle diameter of primary particles: 40 nm, hydrophobically treated with dimethylpolysiloxane), which is an inorganic fine particle aggregate, was mixed with PTFE particles and a volatile additive using a V-type mixer to obtain a paste. As the PTFE particles, POLYFLON PTFE F-104 (average particle diameter: 550 μm) manufactured by Daikin Industries, Ltd., was used. As the volatile additive, dodecane was used. The PTFE particles were added such that the weight ratio between the PTFE particles and the inorganic fine particle aggregate was 40:60. The volatile additive was added such that the amount thereof was 50 parts by weight per 100 parts by weight of the total of the PTFE particles and the inorganic fine particle aggregate. The rotation speed of the mixer was 10 rpm, the mixing time was 5 minutes, and the mixing temperature was 24° C. Next, the obtained paste was passed between a pair of rolling rolls to be molded into a substantially-elliptical mother sheet (sheet-shaped molded body) having a thickness of 3 mm, a width (short diameter) of 10 to 50 mm, and a length (long diameter) of 150 mm. Next, two pieces of the formed mother sheet were aligned in the rolling direction and stacked, and the stacked sheets were rolled by passing the sheets again between the above rolling rolls in the same rolling direction as before, to produce a first rolled laminated sheet. Next, two pieces of the first rolled laminated sheet were stacked, and the stacked sheets were rotated by 90 degrees in the in-plane direction with respect to the previous rolling direction, and rolled by passing the sheets again between the above rolling rolls, to produce a second rolled laminated sheet. Next, two pieces of the second rolled laminated sheet were stacked, and the stacked sheets were rolled by passing the sheets again between the above rolling rolls in the same rolling direction as for the first rolled laminated sheet, to produce a third rolled laminated sheet. Next, two pieces of the third rolled laminated sheet were stacked, and the stacked sheets were rolled by passing the sheets again between the above rolling rolls in the same rolling direction as for the second rolled laminated sheet, to produce a fourth rolled laminated sheet. Next, two pieces of the fourth rolled laminated sheet were stacked, and the stacked sheets were rolled by passing the sheets again between the above rolling rolls in the same rolling direction as for the third rolled laminated sheet, to produce a fifth rolled laminated sheet. Next, the fifth rolled laminated sheet was rolled multiple times in the same rolling direction as for the fourth rolled laminated sheet, with the gap between the rolling rolls narrowed by 0.5 mm each time, to obtain a sheet having a thickness of about 0.18 mm. Next, the obtained sheet was heated at 150° C. for 20 minutes to remove the volatile additive, and was further pressure-molded (pressure: 1 MPa) at 380° C. for 5 minutes to produce a plate-shaped composite material having a thickness of about 0.12 mm.

The evaluation results for the substrates of the Examples and the Comparative Examples are shown in Table 1 below.

TABLE 1

| | | | | | Side air | | | | Compressive | Side water |
|---|---|---|---|---|---|---|---|---|---|---|
| | | | | Average pore | permeation | | | | elastic | entry |
| | | Thickness | Porosity | diameter LA | amount | DR₃₀ | DR_{0.5} | TR | modulus | pressure |
| | | (μm) | (%) | (μm) | (mL/min/kPa) | (%) | (%) | (%) | (MPa) | (kPa) |
| Ex. | 1 | 300 | 65 | 1.12 | 0.38 | 49.0 | 0.2 | 42 | 3.87 | 110 |
| | 2 | 70 | 73 | 0.65 | 0.01 | 53.4 | 1.4 | 71 | 1.79 | 210 |
| | 3 | 70 | 82 | 1.15 | 0.03 | 51.0 | 10.0 | 54 | 0.72 | 115 |
| | 4 | 130 | 80 | 1.06 | 0.03 | 59.0 | 16.0 | 71 | 0.65 | 95 |
| | 5 | 70 | 86 | 2.23 | 0.20 | 68.1 | 22.3 | 86 | 0.83 | 50 |
| | 6 | 60 | 81 | 0.07 | 0.01 | 62.0 | 23.0 | 81 | 0.71 | 145 |
| | 7 | 220 | 51 | 4.8 | 0.69 | 0.2 | 0 | 0 | 0.55 | 40 |
| | 8 | 80 | 70 | 13.0 | 7.4 | 2.5 | 1.9 | — | 0.54 | 3 |
| | 9 | 40 | 47 | 18.0 | 0.08 | 3.8 | 1.3 | — | 4.04 | 18 |
| | 10 | 100 | 35 | 13.0 | 3.3 | 16.5 | 1.4 | — | 3.47 | 2 |
| | 11 | 180 | 49 | 11.0 | 6.4 | 23.3 | 0.9 | — | 5.52 | 2 |
| | 12 | 320 | 76 | 0.11 | 0.03 | 47.6 | 2.9 | 22 | 6.1 | 215 |
| | 13 | 350 | 82 | 0.14 | 0.03 | 51.4 | 6.0 | 29 | 8.8 | 155 |
| | 14 | 330 | 69 | 0.10 | 0.05 | 19.1 | 6.9 | 57 | 4.75 | 45 |
| | 15 | 140 | 78 | 1.26 | 0.52 | 59.9 | 1.4 | 49 | 3.60 | 60 |
| | 16 | 200 | 32 | 25.65 | 0.38 | 29.7 | 0.8 | — | 5.27 | 58 |
| | 17 | 200 | 45 | 88.84 | 1.40 | 42.5 | 2.1 | — | 3.46 | 35 |
| Comp. | 1 | 16 | 48 | 0.08 | 0 | 3.1 | 0 | — | 2.66 | >1000 |
| Ex. | 2 | 370 | 25 | 2.6 | 0 | 1.2 | 0.1 | — | 3.35 | >300 |
| | 3 | 10 | 40 | 0.1 | 0 | 5.0 | 0 | — | 1.66 | >1000 |
| | 4 | 120 | 50 | 0.08 | 0 | 6.2 | 1.7 | 21 | 11.0 | >400 |

* “—” indicates no measurement.

### INDUSTRIAL APPLICABILITY

The cover member of the present invention can be used, for example, for the manufacture of semiconductor device packages. The cover member of the present invention may be removed by re-peeling after covering an object only during a specific treatment.

1. A cover member configured to be placed on a placement face so as to cover an object, the cover member comprising:
a cover sheet having a shape configured to cover the object in a state of being placed on the placement face; and
an adhesive layer joined to the cover sheet and configured to fix the cover member to the placement face, wherein
the adhesive layer includes a double-sided adhesive sheet,
the double-sided adhesive sheet has a structure in which a first adhesive agent layer, a substrate, and a second adhesive agent layer are laminated in this order, the substrate has a porous structure,
the substrate has a porosity of 30% or more,
when the porosity of the substrate is 30% or more and 50% or less, the substrate has an average pore diameter of 10 μm or more, and
when the porosity of the substrate is more than 50%, the average pore diameter is 0.05 μm or more.

2. The cover member according to claim 1, wherein the substrate contains a heat-resistant material.

3. The cover member according to claim 2, wherein the heat-resistant material is at least one selected from a fluorine resin and a silicon compound.

4. The cover member according to claim 1, wherein the substrate is a stretched porous resin sheet or a porous particle aggregated sheet.

5. The cover member according to claim 1, wherein the substrate has a deformation ratio of 60% or less in a thickness direction thereof when the substrate is compressed in the thickness direction at a pressure of 30 MPa.

6. The cover member according to claim 1, wherein the substrate has a deformation ratio of 20% or less in a thickness direction thereof when the substrate is compressed in the thickness direction at a pressure of 0.5 MPa.

7. The cover member according to claim 1, wherein the substrate has a side air permeation amount of 0.005 mL/min/kPa or more.

8. The cover member according to claim 1, wherein at least one selected from the first adhesive agent layer and the second adhesive agent layer is a pressure-sensitive adhesive agent layer.

9. The cover member according to claim 1, wherein at least one selected from the first adhesive agent layer and the second adhesive agent layer is an acrylic adhesive agent layer or a silicone adhesive agent layer.

10. The cover member according to claim 1, wherein the adhesive layer has re-peelability from the placement face.

11. The cover member according to claim 10, wherein the adhesive layer has an adhesive strength of 0.05 N/20 mm or more and less than 5.0 N/20 mm to the placement face.

12. The cover member according to claim 10, wherein
the adhesive layer includes the double-sided adhesive sheet and a re-peelable adhesive agent layer, and
the cover member is placed on the placement face via the re-peelable adhesive agent layer.

13. The cover member according to claim 1, wherein the adhesive layer has a shape corresponding to a peripheral portion of the cover sheet when viewed in a direction perpendicular to a principal surface of the cover sheet, and is joined to the peripheral portion.

14. The cover member according to claim 1, wherein the cover sheet has no air permeability in a thickness direction thereof.

15. The cover member according to claim 1, wherein the cover sheet is an optically transparent sheet.

16. The cover member according to claim 1, wherein the cover sheet contains at least one selected from a heat-resistant resin and glass.

17. The cover member according to claim 16, wherein the heat-resistant resin is polyimide.

18. The cover member according to claim 1, wherein the cover sheet includes an optical lens.

19. The cover member according to claim 1, wherein the cover sheet has an area of 3500 mm² or less.

20. The cover member according to claim 1, wherein
the cover member is placed so as to cover a semiconductor device with a face of a substrate on which the semiconductor device is mounted being the placement face, and
the cover member is used for forming a semiconductor device package in which the semiconductor device is housed in an inner space of the semiconductor device package by placing the cover member on the placement face.

21. A member supplying sheet comprising:
a substrate sheet; and
at least one cover member placed on the substrate sheet, wherein
the cover member is the cover member according to claim 1.

22. A double-sided adhesive sheet having a structure in which a first adhesive agent layer, a substrate, and a second adhesive agent layer are laminated in this order, wherein
the substrate has a porous structure,
the substrate has a porosity of 30% or more,
when the porosity of the substrate is 30% or more and 50% or less, the substrate has an average pore diameter of 10 μm or more, and
when the porosity of the substrate is more than 50%, the average pore diameter is 0.05 μm or more.

23. A seal member configured to be placed between a first component and a second component when the first component and the second component are joined, and prevent passage of foreign matter between an inner space surrounded by the first component and the second component joined together and an outside, wherein
the seal member has an air flow path between the inner space and the outside,
the seal member comprises the double-sided adhesive sheet according to claim 22, and
the substrate of the double-sided adhesive sheet is included in the air flow path.

24. The seal member according to claim 23, having a ring shape or a frame shape.

25. The seal member according to claim 24, wherein a region surrounded by the seal member has an area of 50 cm² or more.

26. The seal member according to claim 23, having a width of 5 mm or less.

27. A member supplying sheet comprising:
a substrate sheet; and
at least one seal member placed on the substrate sheet, wherein the seal member is the seal member according to claim 23.
